(19) United States
(12) Patent Application Publication
(10) Pub. No.: US 2005/0202638 A1
(43) Pub. Date: Sep. 15, 2005

(54) Method of reducing step height

(76) Inventors: Jia-Wei Yang, Hsinchu (TW); Da-Pong Chang, Taipei (TW)

Correspondence Address: BIRCH STEWART KOLASCH & BIRCH, PO BOX 747, FALLS CHURCH, VA, 22040-0747, US

(21) Appl. No.: 10/796,965

(22) Filed: Mar. 11, 2004

(51) Int. Cl. H01L 21/336; H01L 21/8234

(52) U.S. Cl. 438/275; 438/294

(57) ABSTRACT

A method of reducing substrate step height. The method includes providing a substrate having a low-voltage device area and high-voltage device area divided by an isolation structure, forming an oxidation mask at least approximately 500 Å thick over the low-voltage device area and parts of the isolation structure, forming a first oxide layer on the exposed high-voltage device area and isolation structure using the oxidation mask as a mask, removing the oxidation mask, and forming a second oxide layer, thinner than the first oxide layer, on the low-voltage device layer.

### BACKGROUND OF THE INVENTION

1. Field of the Invention

The present invention relates to a semiconductor process, and more specifically to a method of reducing step height when forming high-voltage and low-voltage device areas on a substrate.

2. Description of the Related Art

FIGS. 1A through 1E are cross-sections of a conventional process forming high-voltage and low-voltage device areas. The substrate 100 in FIG. 1A has a high-voltage area 101 and low-voltage area 102 divided by a shallow trench isolation (STI) structure 110.

In FIG. 1B, an oxide layer 120 about 1000 to 2000 Å thick is formed on the substrate 100. In FIG. 1C, a patterned mask layer 130 is formed on the oxide layer 120. The oxide layer 120 on the low-voltage device area 101 is removed using the patterned mask layer 130 as an etch mask, leaving that on the high-voltage device area 102 to act as gate oxide. Further, over-etching is usually performed to ensure complete removal of the oxide layer 120 from the low-voltage device area 102, resulting in etching and recessing of parts of the STI structure 110 because the STI structure 110 is usually an oxide layer.

In FIG. 1D, the patterned mask layer 130 is removed, followed by the formation of an oxide layer 140 about 32 to 125 Å thick on the low-voltage device area 102 using thermal oxidation. The step height H of substrate 100 can be as large as 1700 Å resulting from the recessed STI structure 110, and usually has a steep slope. Therefore, as shown in FIG. 1E, when a polycrystalline silicon layer 160 formed on the substrate 100 is patterned in subsequent gate forming process, polycrystalline silicon spacers 161 usually remain on high sidewalls, negatively affecting the process yield and electrical performance of the devices.

FIGS. 2A and 2B are cross-sections of a method of forming gate oxide layers of different thicknesses as disclosed by Chu et al. in U.S. Pat. No. 6,130,168. The substrate 10 has a memory cell area A, low-voltage device area B, and high-voltage device area C divided by STI structures 20. A tunneling oxide layer 21 and polycrystalline silicon layer 31 are sequentially formed on the memory cell area A.

In FIG. 2A, an ONO layer 40, acting as a dielectric layer of a capacitor in a gate electrode of a flash memory, about 100 to 500 Å thick is formed on substrate 10. The ONO layer 40 on the high-voltage layer is then removed, followed by formation of a first gate oxide layer 22 about 100 to 400 Å thick on the high-voltage device area C using thermal oxidation, the ONO layer 40 acting as a hard mask of low-voltage device area B.

In FIG. 2B, the ONO layer 40 on the low-voltage device area B is removed, leaving that on the memory cell area A, followed by formation of a second gate oxide layer 23 on the low-voltage device area B using thermal oxidation and increase of the first gate dielectric layer's thickness to about 100 to 500 Å.

The first gate oxide layer 22, about 100 to 500 Å thick, however, is designed for performance of a working voltage of 5V or lower. Gate oxide layers of some devices performing at 40V, 100V, or higher must be as thick as 1000 Å, 2000 Å, or more to provide sufficient electrical reliability. The ONO layer 40, acting as the hard mask of low-voltage device area, is usually about 100 to 500 Å thick and cannot be made thicker due to its role as the dielectric layer of the capacitor in the gate of the flash memory cell in memory cell area A. Oxygen may penetrate the ONO layer 40 on the low-voltage device area B as a result of insufficient thickness during the formation of the first gate oxide layer 22 about 1000 to 2000 Å when desired, resulting in formation of an unwanted oxide layer between substrate 10 and ONO layer 40, thereby negatively affecting process yield and electrical performance.

### SUMMARY OF THE INVENTION

Thus, the main object of the present invention is to provide a method of reducing step height, providing the minimum step height when forming high-voltage and low-voltage device areas on a substrate, in order to improve process yield and electrical performance.

In order to achieve the described objects, the present invention provides a method of reducing step height. First, a substrate, comprising a low-voltage device area and high-voltage device area divided by an isolation structure, is provided. The substrate further comprises a pad oxide layer on the surface of the low-voltage device area and high-voltage device area. Then, a silicon nitride layer and patterned mask layer are sequentially formed overlying the substrate. Silicon nitride layer thickness is at least about 500 Å thick. The patterned mask layer exposes the silicon nitride layer in the high-voltage device area and parts of the isolation structure adjacent thereto. Next, the exposed silicon nitride layer is anisotropically etched using the mask layer, exposing the high-voltage device area and parts of the isolation structure. Next, the patterned mask layer and pad oxide on the surface of the high-voltage device area are sequentially removed. Next, a first oxide layer is formed on the exposed high-voltage device area and isolation structure using the silicon nitride layer as a mask. Further, the remaining silicon nitride layer and pad oxide layer on the surface of the low-voltage device area are sequentially removed. Finally, a second oxide layer, thinner than the first oxide layer, is formed on the low-voltage device layer.

### BRIEF DESCRIPTION OF THE DRAWINGS

The present invention can be more fully understood by reading the subsequent detailed description in conjunction with the examples and references made to the accompanying drawings, wherein:

FIGS. 1A through 1E are cross sections of a conventional process of forming high-voltage and low-voltage device areas.

FIGS. 2A and 2B are cross-sections of a method of forming gate oxide layers of different thickness as disclosed by Chu et al. in U.S. Pat. No. 6,130,168.

FIGS. 3A through 3E are cross-sections of a method of reducing step height of the present invention.

FIG. 4 is a cross-section of an application of a structure formed by the present invention.

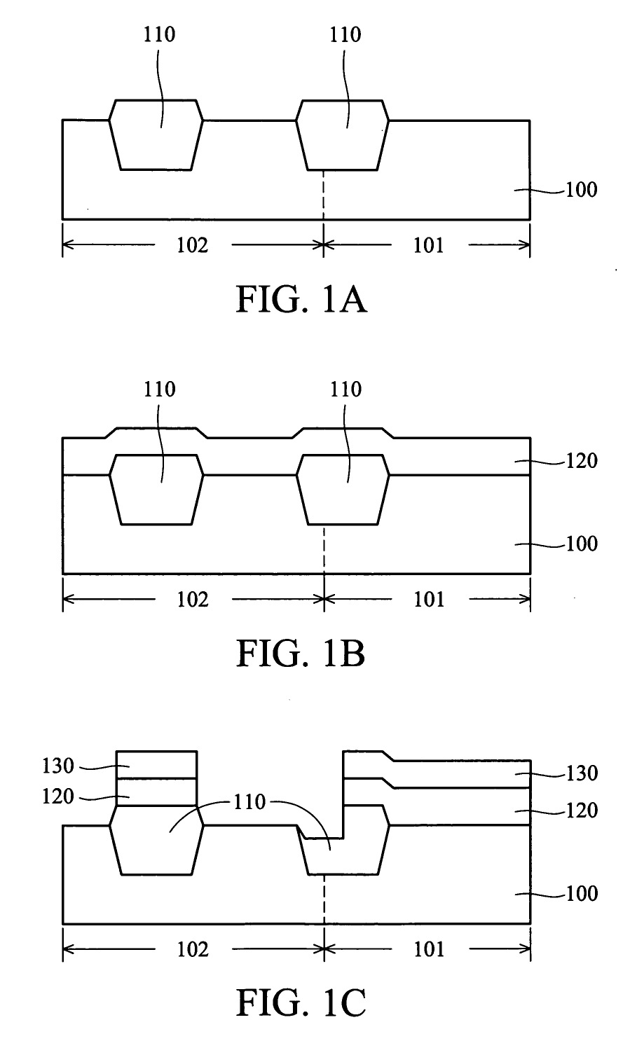

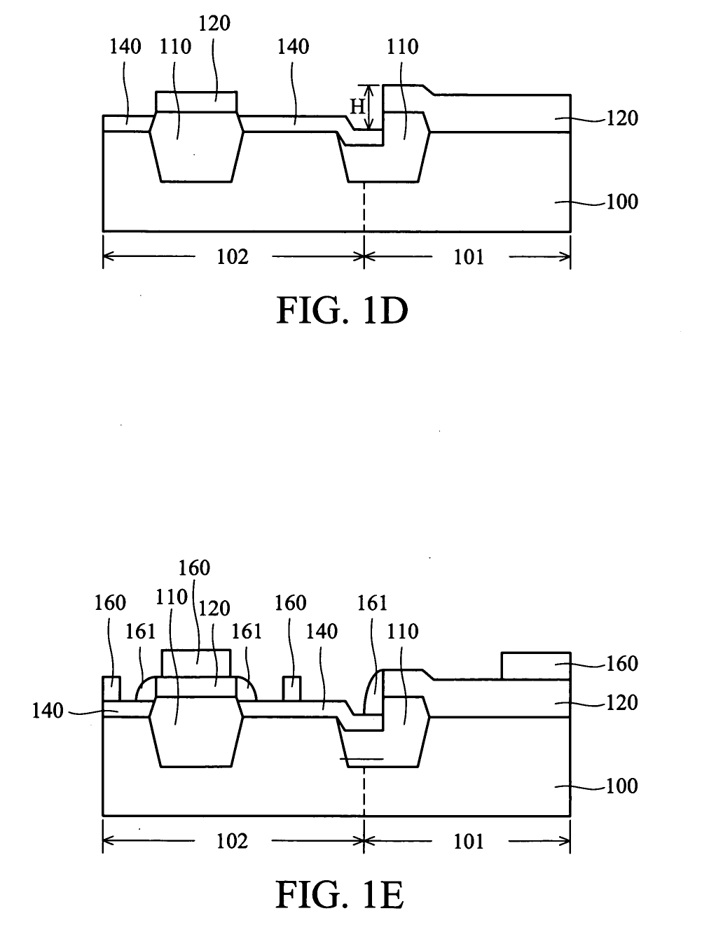

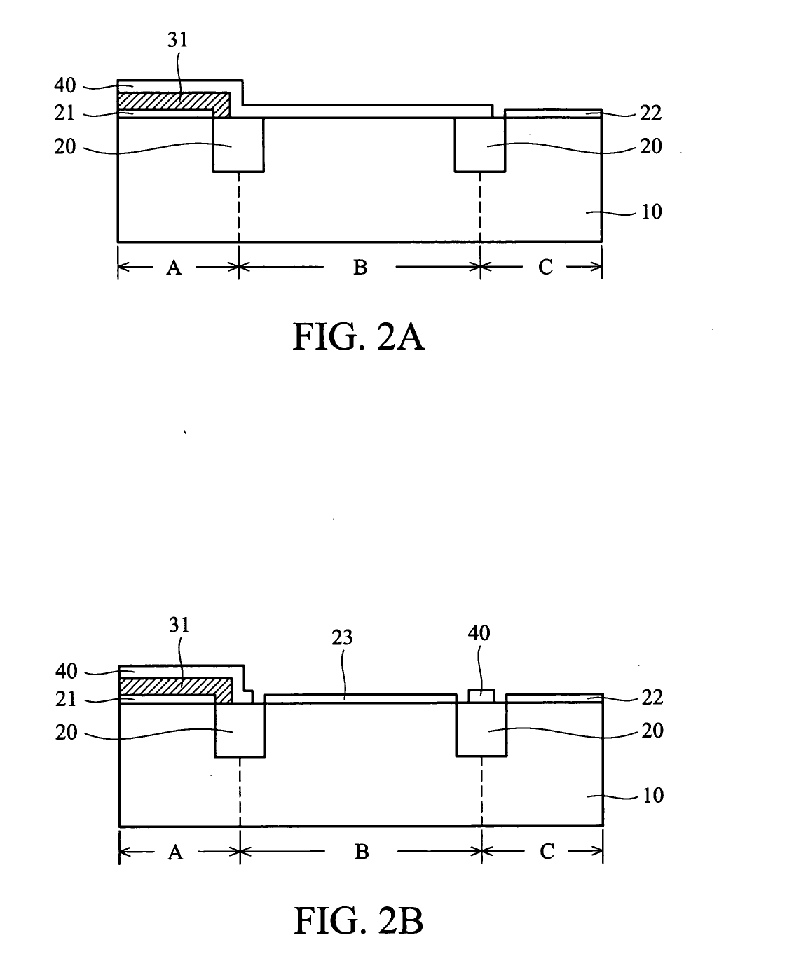

### DETAILED DESCRIPTION OF THE INVENTION

The following embodiments are intended to illustrate the invention more fully without limiting the scope of the claims, since numerous modifications and variations will be apparent to those skilled in this art.

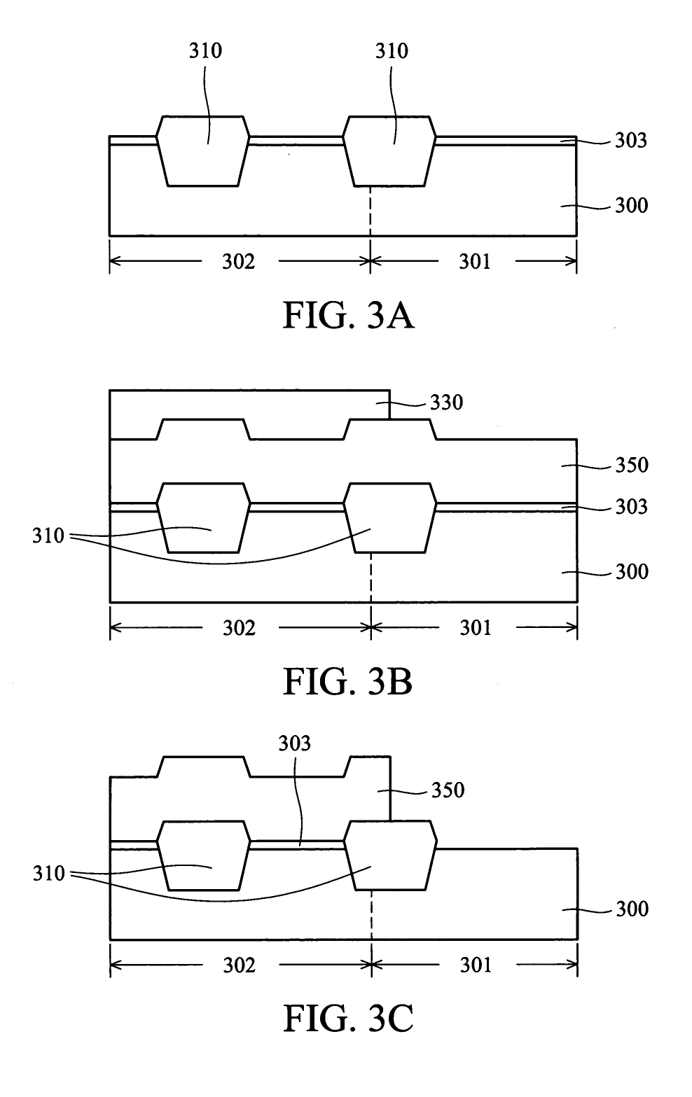

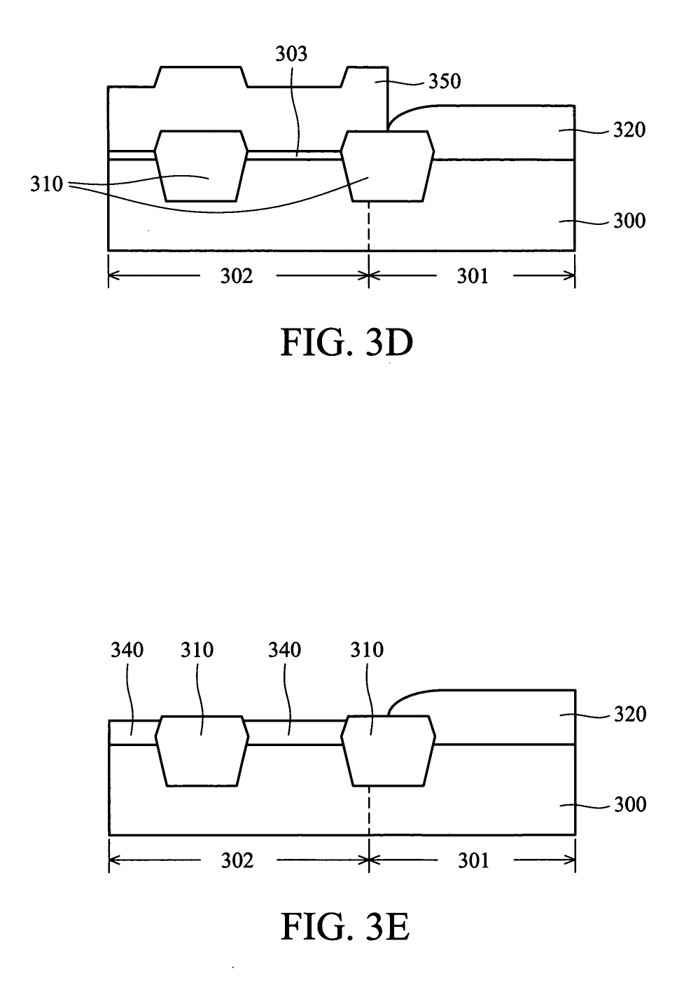

FIGS. 3A through 3E are cross-sections of a method of reducing step height of the present invention.

In FIG. 3A, a substrate 300, usually single-crystalline silicon, is provided. The substrate 300 is usually covered by a pad oxide layer 303 on a surface. The substrate 300 comprises a high-voltage device area 301 and low-voltage device area 302 divided by an isolation structure 310. The isolation structure 310 can be a shallow trench isolation (STI) structure or field oxide (FOX) layer. In this embodiment, the pad oxide layer 303 is approximately 200 Å thick, and the isolation structure 310 is STI, and usually an oxide layer.

In FIG. 3B, a silicon nitride layer 350, preferably as thick as 500 Å or more, is formed on substrate 300, subsequently acting as an oxidation mask. In this embodiment, the silicon nitride layer 350 is approximately 1500 Å thick. A patterned mask layer 330, such as a resist layer, is formed overlying substrate 300, exposing the nitride layer 350 on the high-voltage device area 301 and parts of the isolation structure 310 adjacent thereto.

In FIG. 3C, the exposed silicon nitride layer 350 is anisotropically etched. Thus, the silicon nitride layer 350 on the high-voltage device area 301 and parts of the isolation structure 310 adjacent thereto is removed. The patterned mask layer 330 and pad oxide layer 303 on the high-voltage device area 301 are then sequentially removed, exposing the substrate 300 in the high-voltage device area 301.

In FIG. 3D, a first oxide layer 320 is formed on the high-voltage device area 301 and parts of the isolation structure 310 adjacent thereto by a method such as thermal oxidation using the remaining silicon nitride layer 350 as an oxidation mask. The first oxide layer 320 is thin directly on the isolation structure 310, thickening gradually to a predetermined value, and approximately maintaining the thickness in areas further from the low-voltage device structure 302 resulting from the isolation structure 310 providing longer diffusion paths for oxygen. The first oxide layer 320 directly on the high-voltage device area 301 is approximately evenly as thick as the predetermined value, preferably between 1000 and 2000 Å. Further, the silicon nitride layer 350, as thick as 500 Å or more, sufficiently prevents oxygen from contacting the substrate 300 in the low-voltage device area 302 when forming the first oxide layer 320, about 1000 and 2000 Å thick. Thus, the first oxide layer 320 is formed only on the high-voltage device area 301 and parts of the isolation structure 310 adjacent thereto, such that the high-voltage device area can perform at 40V, 100V, or higher voltage.

Finally in FIG. 3E, the silicon nitride layer 350 on the low-voltage layer 302 is removed preferably by a method providing a higher selective ratio of the silicon nitride layer 350 to an oxide, such as wet etching using hot phosphoric acid, in order to completely etch the silicon nitride layer 350 without damaging the first oxide layer 320, isolation structure 310, and substrate 300 beneath pad oxide layer 303. A second oxide layer 340, thinner than the first oxide layer 320, preferably about 32 to 125 Å thick, is then formed on the low-voltage device area 302 by a method such as thermal oxidation.

Because the first oxide layer 320 is thin directly on the isolation structure 310 and the isolation structure 310 is not substantially damaged, the step height of substrate 300 can be decrease to about 400 to 500 Å and with a gradual slope resulting from the first oxide layer 320 thickening gradually to a predetermined value, and maintaining the thickness in areas further from the low-voltage device structure 302.

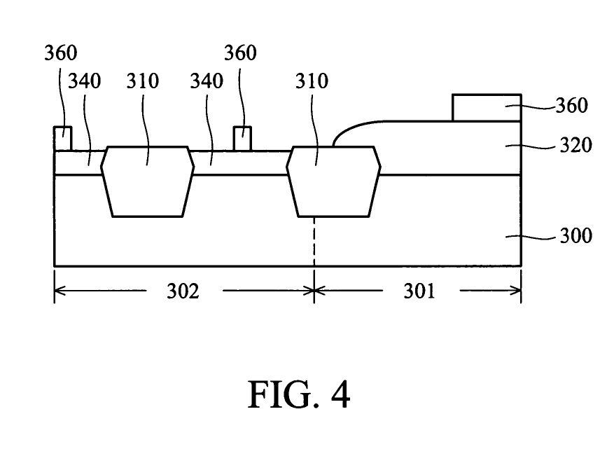

FIG. 4 is a cross-section of an application of the present invention. In the subsequent gate forming process of the step shown in FIG. 3E, a polycrystalline silicon layer 360 is blanketly formed overlying substrate 300. When the polycrystalline silicon layer 360 is patterned, substantially no unwanted polycrystalline silicon layer 360 remains, due to the reduced step height and gradual slope, providing improved process yield and electrical performance, achieving the main object of the present invention.

Although the present invention has been particularly shown and described with reference to the preferred specific embodiments and examples, it is anticipated that alterations and modifications thereof will no doubt become apparent to those skilled in the art. It is therefore intended that the following claims be interpreted as covering all such alteration and modifications as fall within the true spirit and scope of the present invention.

1. A method of reducing step height, comprising:
providing a substrate comprising a low-voltage device area and high-voltage device area divided by an isolation structure and a pad oxide layer on the surface of the low-voltage device area and high-voltage device area;
sequentially forming a silicon nitride layer of at least about 500 Å thick and a patterned mask layer, exposing the silicon nitride layer on the high-voltage device area and parts of the isolation structure adjacent thereto, overlying the substrate;
anisotropically etching the exposed silicon nitride layer using the mask layer as an etch mask, exposing the high-voltage device area and parts of the isolation structure;
sequentially removing the patterned mask layer and pad oxide from the surface of the high-voltage device area;
forming a first oxide layer on the exposed high-voltage device area and isolation structure using the silicon nitride layer as a mask;
sequentially removing the remaining silicon nitride layer and pad oxide layer from the surface of the low-voltage device area; and
forming a second oxide layer, thinner than the first oxide layer, on the low-voltage device layer.

2. The method as claimed in claim 1, wherein the isolation structure comprises a shallow trench isolation (STI) structure or field oxide (FOX) layer.

3. The method as claimed in claim 1, wherein the first oxide is formed by thermal oxidation.

4. The method as claimed in claim 1, wherein the first oxide layer thickens gradually to a predetermined value and approximately maintains the thickness in areas further from the low-voltage device structure.

5. The method as claimed in claim 1, wherein the first oxide layer is about 1000 to 2000 Å thick.

6. The method as claimed in claim 1, wherein the second oxide layer is formed by thermal oxidation.

7. The method as claimed in claim 1, wherein the second oxide layer is about 32 to 125 Å thick.

8. The method as claimed in claim 1, wherein the silicon nitride layer on the low-voltage device area is removed by hot phosphoric acid.

9. A method of reducing step height, comprising:
providing a substrate having a low-voltage device area and high-voltage device area divided by an isolation structure;
forming an oxidation mask at least approximately 500 Å thick over the low-voltage device area and parts of the isolation structure;
forming a first oxide layer on the exposed high-voltage device area and isolation structure using the oxidation mask as a mask;
removing the oxidation mask; and
forming a second oxide layer, thinner than the first oxide layer, on the low-voltage device layer.

10. The method as claimed in claim 9, wherein the isolation structure comprises a shallow trench isolation (STI) structure or field oxide (FOX) layer.

11. The method as claimed in claim 9, wherein the oxidation mask is a silicon nitride layer.

12. The method as claimed in claim 9, wherein the first oxidation layer is formed by thermal oxidation.

13. The method as claimed in claim 9, wherein the first oxide layer thickens gradually to a predetermined value and approximately maintains the thickness in areas further from the low-voltage device structure.

14. The method as claimed in claim 9, wherein the first oxide layer is about 1000 to 2000 Å thick.

15. The method as claimed in claim 9, wherein the second oxidation layer is formed by thermal oxidation.

16. The method as claimed in claim 9, wherein the second oxide layer is about 32 to 125 Å thick.

17. The method as claimed claim 9, wherein the oxidation mask is removed by hot phosphoric acid.

18. The method as claimed in claim 9, further comprising a pad oxide layer on the surface of the low-voltage device area and high-voltage device layer.

19. The composite as claimed in claim 9, further comprising removing the pad oxide layer from the low-voltage device layer when the oxidation mask is removed.
